(19) United States
(12) Patent Application Publication
(10) Pub. No.: US 2010/0164037 A1
(43) Pub. Date: Jul. 1, 2010

(54) METHOD FOR MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/643,429

(22) Filed: Dec. 21, 2009

(30) Foreign Application Priority Data
Dec. 29, 2008 (KR) 10-2008-0135259

(51) Int. Cl. H01L 31/0232; H01L 31/18

(52) U.S. Cl. 257/432; 438/69; 257/E31.127; 257/E21.575

(57) ABSTRACT

A method of manufacturing an image sensor. A method of manufacturing an image sensor may include forming a circuit area including a circuitry on and/or over a semiconductor substrate having a pixel area and/or a peripheral area, provided with a photodiode. A method may include forming a metal interconnection layer, which may include a metal interconnection on and/or over a interlayer dielectric layer, on and/or over a circuit area, forming a trench over a metal interconnection layer of a pixel area, performing a cleaning process on and/or over a the metal interconnection layer including a trench, and/or forming a micro-lens on and/or over a bottom surface of a trench of a metal interconnection layer.

The present application claims priority under 35 U.S.C. 119 to Korean Patent Application No. 10-2008-0135259 (filed on Dec. 29, 2008) which is hereby incorporated by reference in its entirety.

### BACKGROUND

Embodiments relate to an image sensor, and a method of manufacturing an image sensor.

A semiconductor device may convert optical images into electrical signals. A semiconductor device may be classified as a charge coupled device (CCD) and/or a complementary metal oxide semiconductor (CMOS) image sensor. A CMOS image sensor may include a structure in which a photodiode area, which may convert optical signals into electrical signals, may be horizontally arranged with a transistor area, which may processes electrical signals. Studies and/or research may have been pursued to maximize light sensitivity, for example by minimizing a distance between a photodiode and a micro-lens when an image sensor may be manufactured. To reduce a relative distance between a photodiode and a micro-lens, a micro-lens may be formed after forming a trench on and/or over an interlayer dielectric layer. However, a trench may have a relatively bad surface profile, which may be a defect source of an image sensor.

Accordingly, there is a need for an image sensor and a method of manufacturing an image sensor.

### SUMMARY

According to embodiments, a method of manufacturing an image sensor may include forming a circuit area including a circuitry on and/or over a semiconductor substrate, which may include a pixel area and/or a peripheral area and/or may be provided having a photodiode. In embodiments, a method of manufacturing an image sensor may include forming a metal interconnection layer, which may include a metal interconnection on and/or over an interlayer dielectric layer, on and/or over a circuitry area. In embodiments, a method of manufacturing an image sensor may include forming a trench on and/or over a metal interconnection layer of a pixel area. In embodiments, a method of manufacturing an image sensor may include performing a cleaning process on and/or over a metal interconnection layer formed thereover with a trench. In embodiments, a method of manufacturing an image sensor may include forming a micro-lens on and/or over a bottom surface of a trench of a metal interconnection layer.

### DRAWINGS

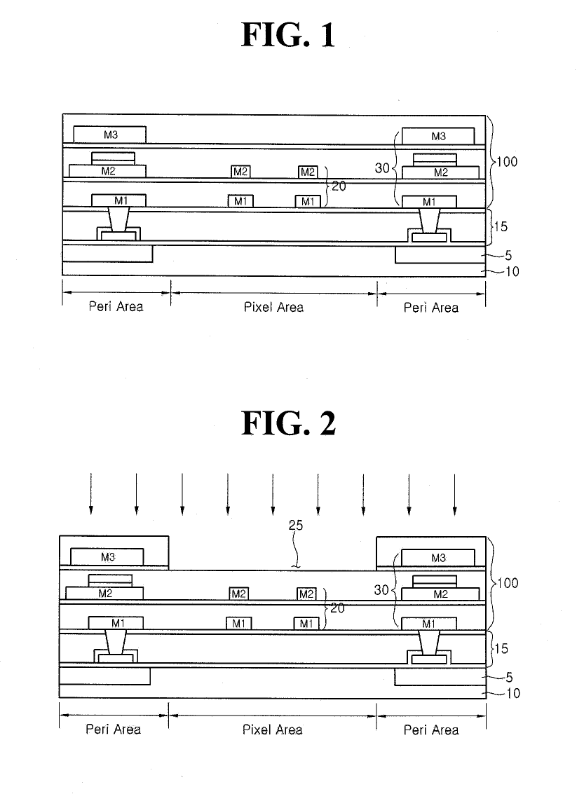

Example FIG. 1 to FIG. 3 are sectional views illustrating a method of manufacturing an image sensor in accordance with embodiments.

### DESCRIPTION

Embodiments relate to a method of manufacturing an image sensor and devices thereof. According to embodiments, a method of manufacturing an image sensor may be capable of minimizing a defect of a device, for example by relatively improving a profile of an interlayer dielectric layer. Embodiments may relate to a CMOS image sensor, and/or may be applicable to all image sensors, for example a CCD image sensor, which may require a photodiode. Referring to example FIG. 1 to FIG. 3, a method of manufacturing an image sensor in accordance with embodiments is illustrated.

Referring to FIG. 1, a pixel area and/or a peripheral (peri) area may be defined. According to embodiments, circuit area 15 may include a transistor, and/or may be formed on and/or over semiconductor substrate 10 including a photodiode and/or isolation layer 5. In embodiments, circuit area 15 may be formed using an interlayer dielectric layer including a transistor. In embodiments, a photodiode may be formed on and/or over circuit area 15 of a pixel area.

According to embodiments, metal interconnection layer 100 including a metal interconnection may be formed on and/or over circuit area 15. In embodiments, second metal interconnection 30 of a peri area may be formed higher relative to first metal interconnection 20 of a pixel area. In embodiments, second metal interconnection 30 of a peri area may include three metal layers, and/or first metal interconnection 20 of a pixel area may include two metal layers. In embodiments, a number of metal layers of a pixel area and/or a peri area may be changed.

Referring to FIG. 2, trench 25 may be formed on and/or over a interlayer dielectric layer of metal interconnection layer 100. According to embodiments, trench 25 may be formed on and/or over an interlayer dielectric layer of a pixel area, and/or formed on and/or over first metal interconnection 20 of a pixel area. In embodiments, trench 25 may be formed to minimize a distance between a photodiode and a micro-lens which may be formed later, such that sensitivity of an image sensor may be maximized. In embodiments, trench 25 may be formed through an etching process after forming a photoresist pattern on and/or over metal interconnection layer 100.

According to embodiments, trench 25 may be formed, and/or a photoresist pattern may be substantially removed through an ashing process. In embodiments, polymer which may be generated when trench 25 may be formed may be substantially removed, for example by an additional process. In embodiments, trench 25 may be formed through an etching process, and/or a surface profile of trench 25 may be relatively irregular due to an etching process. A relatively irregular surface profile may become a defect source of an image sensor. Incident light may be concentrated at a sidewall of trench 25 due to a roughness of a sidewall of trench 25, such that a dark current of an image sensor may be maximized. In embodiments, trench 25 may be formed, and/or a first cleaning process and/or a second cleaning process may be performed such that a surface profile of trench 25 may be substantially uniform.

According to embodiments, a first cleaning process may be performed by employing a tetra methyl ammonium hydroxide (TMAH) chemical, and/or a second cleaning process may be performed by employing a HNO₃ chemical, which may provide surface treatment. In embodiments, a first cleaning process may be performed between approximately 20 seconds and 30 minutes using a TMAH chemical. In embodiments, a TMAH chemical may include a density between approximately 10% and 60%. In embodiments, a second cleaning process may be performed between approximately 5 seconds and 60 seconds using a HNO₃ chemical.

According to embodiments, a TMAH and/or a HNO₃ chemical may be sprayed through a spin scheme, for example at a rotational speed between approximately 200 rpm and 800 rpm. In embodiments, a temperature may be between approximately 25° C. and 40° C. In embodiments, a TMAH and/or a HNO₃ chemical may not be limited to a spin scheme. In embodiments, for example, a nitrogen (N₂) dry scheme may be adopted after a quick dump drain (QDR) may be performed. In embodiments, a substantially uniform surface profile of trench 25 may be formed through a first and/or a second cleaning process using TMAH and/or HNO₃, such that a dark signal of an image sensor may be minimized, and/or sensitivity of an image sensor may be maximized.

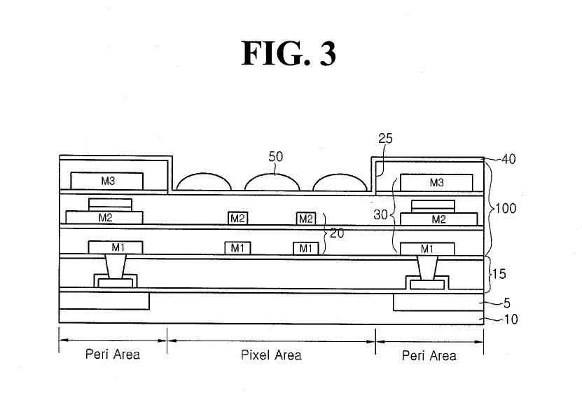

Referring to example FIG. 3, a surface profile of trench 25 may be substantially uniformly formed through a first and/or a second cleaning process. In embodiments, passivation layer 40 may be formed on and/or over metal interconnection layer 100 including trench 25. In embodiments, micro-lens 50 may be formed on and/or over trench 25. In embodiments, passivation layer 40 may be formed using silicon nitride (SiN), which may reference a type of a nitride layer. In embodiments, passivation layer 40 may be formed on and/or over trench 25. In embodiments, micro-lens 50 may be formed using photoresist for a micro-lens. In embodiments, a photoresist layer may be formed on and/or over trench 25, and/or a structure may be selectively exposed and/or developed. In embodiments, a micro-lens pattern corresponding to a unit pixel may be formed.

According to embodiments, a reflow process may be performed such that micro-lens 50 may be formed including a convex dome shape. In embodiments, micro-lens 50 may be positioned on and/or over a bottom surface of trench 25. In embodiments, a gap may be formed between micro-lenses 50 to prevent neighboring micro-lenses from being bridged and/or merged with each other. In embodiments, micro-lens 50 may be formed on and/or over trench 25, and/or a color filter may additionally formed. In embodiments, a photodiode may include a vertical photodiode, such that a color filter may not be formed.

According to embodiments, an image sensor may include a trench, which may be formed on and/or over a metal interconnection layer of a pixel area, which may minimize a distance between a micro-lens and a photodiode. In embodiments, sensitivity of an image sensor may be maximized. In embodiments, a surface profile of a trench formed on and/or over an interlayer dielectric layer may be substantially uniform, such that sensitivity of an image sensor may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a circuit area over a semiconductor substrate comprising a pixel area and a peripheral area including a photodiode;
forming a metal interconnection layer over said circuit area;
forming a trench over an interlayer dielectric layer of said metal interconnection layer;
performing a cleaning process over said metal interconnection layer including the trench; and
forming a micro-lens over a bottom surface of the trench.

2. The method of claim 1, comprising forming a passivation layer over said metal interconnection layer including the trench, prior to forming said micro-lens.

3. The method of claim 2, wherein said passivation layer comprises silicon nitride.

4. The method of claim 1, wherein said cleaning process comprises at least one of a tetra methyl ammonium hydroxide chemical and a HNO₃ chemical.

5. The method of claim 4, wherein said cleaning process comprises:
a first cleaning process including said tetra methyl ammonium hydroxide chemical; and
a second cleaning process performed after said first cleaning process including said HNO₃ chemical.

6. The method of claim 5, wherein said first cleaning process comprises employing said tetra methyl ammonium hydroxide chemical for between approximately 20 seconds and 30 minutes.

7. The method of claim 4, wherein a density of said tetra methyl ammonium hydroxide chemical is in a range between approximately 10% and 60%.

8. The method of claim 4, wherein said cleaning process comprises employing said HNO₃ chemical for between approximately 5 seconds and 60 seconds.

9. The method of claim 3, wherein said cleaning process is performed by spraying said at least one of said tetra methyl ammonium hydroxide chemical and said HNO₃ chemical using a spin scheme.

10. The method of claim 9, wherein said spin scheme comprises at least one of:
a rotational speed between approximately 200 rpm and 800 rpm; and
a temperature between approximately 25° C. and 40° C.

11. The method of claim 1, wherein said metal interconnection layer comprises:
a first metal interconnection formed over said pixel area; and
a second metal interconnection formed over said peripheral area, wherein the trench is formed over said first metal interconnection.

12. The method of claim 1, comprising removing polymer generated when the trench is formed, prior to performing a cleaning process.

13. An apparatus comprising:
a circuit area over a semiconductor substrate comprising a pixel area and a peripheral area including a photodiode;
a metal interconnection layer over said circuit area;
a trench over an interlayer dielectric layer of said metal interconnection layer; and
a micro-lens over a bottom surface of the trench,
wherein said metal interconnection layer including the trench comprises a cleaned portion.

14. The apparatus of claim 13, comprising a passivation layer over said metal interconnection layer including the trench.

15. The apparatus of claim 13, wherein said cleaned portion is cleaned comprising at least one of a tetra methyl ammonium hydroxide chemical and a HNO₃ chemical.

16. The apparatus of claim 15, wherein said cleaning process comprises:
a first cleaning process including said tetra methyl ammonium hydroxide chemical; and
a second cleaning process performed after said first cleaning process including said HNO₃ chemical.

17. The apparatus of claim 16, wherein said first cleaning process comprises employing said tetra methyl ammonium hydroxide chemical for between approximately 20 seconds and 30 minutes.

18. The apparatus of claim 17, wherein said cleaning process is performed by spraying said at least one of said tetra methyl ammonium hydroxide chemical and said HNO₃ chemical using a spin scheme.

19. The apparatus of claim 13, wherein said metal interconnection layer comprises:
a first metal interconnection over said pixel area; and
a second metal interconnection over said peripheral area, wherein the trench is formed over said first metal interconnection.

20. The apparatus of claim 13, comprising a substantially uniform portion.
